(19) United States
(12) Patent Application Publication
(10) Pub. No.: US 2025/0294666 A1
(43) Pub. Date: Sep. 18, 2025

(54) EXPANSION CARD MODULE

(71) Applicant: ASUS GLOBAL PTE. LTD., Singapore (SG)

(72) Inventor: Haiwei Cong, Singapore (SG)

(73) Assignee: ASUS GLOBAL PTE. LTD., Singapore (SG)

(21) Appl. No.: 19/073,009

(22) Filed: Mar. 7, 2025

(30) Foreign Application Priority Data
Mar. 13, 2024 (CN) 202410290673.9

(51) Int. Cl. H05K 1/02; H05K 1/14; H05K 5/03; H05K 7/20

(52) U.S. Cl. CPC H05K 1/0204; H05K 1/142; H05K 5/03; H05K 7/20154; H05K 2201/045; H05K 2201/066; H05K 2201/0999; H05K 2201/10189

(57) ABSTRACT

This disclosure discloses an expansion card module, including an expansion card, a circuit board, a storage unit, and a heat sink. The circuit board is disposed next to the expansion card and includes a first connector and a second connector. The storage unit is pluggably disposed on the first connector of the circuit board. The heat sink is located next to and thermally coupled to the expansion card and storage unit. The storage unit of the expansion card module in this disclosure transmits signals through the circuit board. Since there is no need to transmit signals through the expansion card, the storage unit and the motherboard may have better compatibility. In addition, the storage unit and the expansion card dissipate heat together through the heat sink, thus having a good heat dissipation effect.

### CROSS-REFERENCE TO RELATED APPLICATION

This application claims the priority benefit of China application serial no. 202410290673.9, filed on Mar. 13, 2024. The entirety of the above-mentioned patent application is hereby incorporated by reference herein and made a part of this specification.

### BACKGROUND

### Technical Field

This disclosure relates to an expansion card module, in particular to an expansion card module having good compatibility and heat dissipation.

### Description of Related Art

Currently, some expansion cards are equipped with an additional storage unit, which is connected to the motherboard through a port on the expansion card. However, some motherboards may have mismatch/compatibility problems with such expansion cards with storage units, and may not be able to read the storage units or may only be able to operate part of the functions of the storage units. How to improve the compatibility between expansion card modules and motherboards may be the direction of research in this field.

### SUMMARY

This disclosure mentions an expansion card module, including an expansion card, a circuit board, a storage unit, and a heat sink. The circuit board is disposed next to the expansion card and includes a first connector and a second connector. The storage unit is pluggably disposed on the first connector of the circuit board. The heat sink is located next to the expansion card and storage unit and is thermally coupled to the expansion card and storage unit.

The storage unit of the expansion card module in this disclosure transmits signals through the circuit board. Since there is no need to transmit signals through the expansion card, the storage unit and the motherboard may have better compatibility. In addition, the storage unit of the expansion card module in this disclosure dissipates heat through the heat sink together with the expansion card, thus having a good heat dissipation effect.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate example embodiments of the disclosure and, together with the description, serve to explain the principles of the disclosure.

FIG. 1 to FIG. 3 are schematic diagrams of an expansion card module from different perspectives according to an embodiment of the disclosure.

FIG. 4 is a partially enlarged schematic diagram of the expansion card module of FIG. 3 from another perspective.

FIG. 5 is a schematic diagram concealing a cover plate of FIG. 4 from another perspective.

FIG. 6 is a schematic diagram concealing a cover plate and a fan of FIG. 1.

FIG. 7 is a schematic diagram concealing a heat sink of FIG. 5.

FIG. 8 is a schematic diagram of a circuit board, a storage unit and a connection cable of FIG. 7.

FIG. 9 is a schematic diagram of a bottom surface of a heat sink of FIG. 1.

### DESCRIPTION OF THE EMBODIMENTS

Reference will now be made in detail to the exemplary embodiments of the disclosure, examples of which are illustrated in the accompanying drawings. Whenever possible, the same reference numerals are used in the drawings and descriptions to represent the same or similar parts.

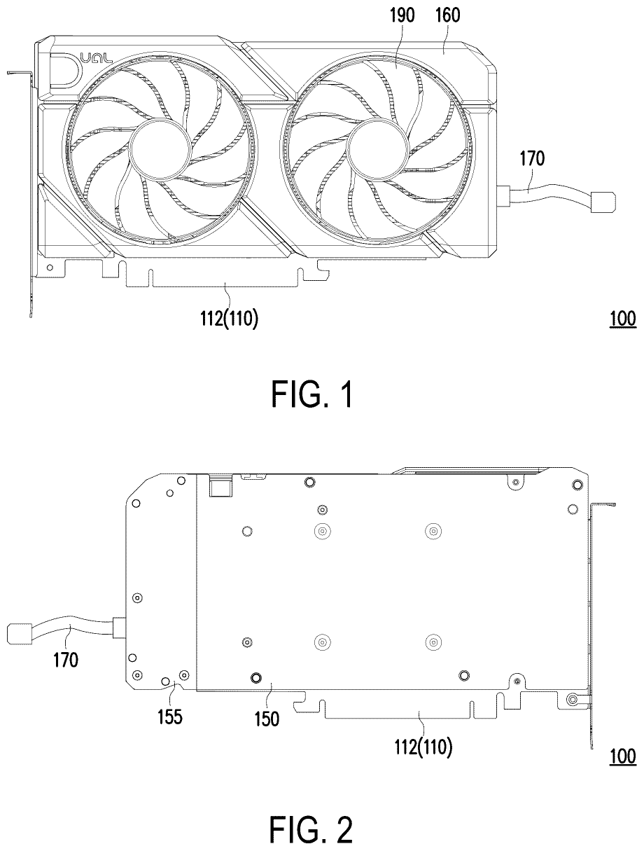

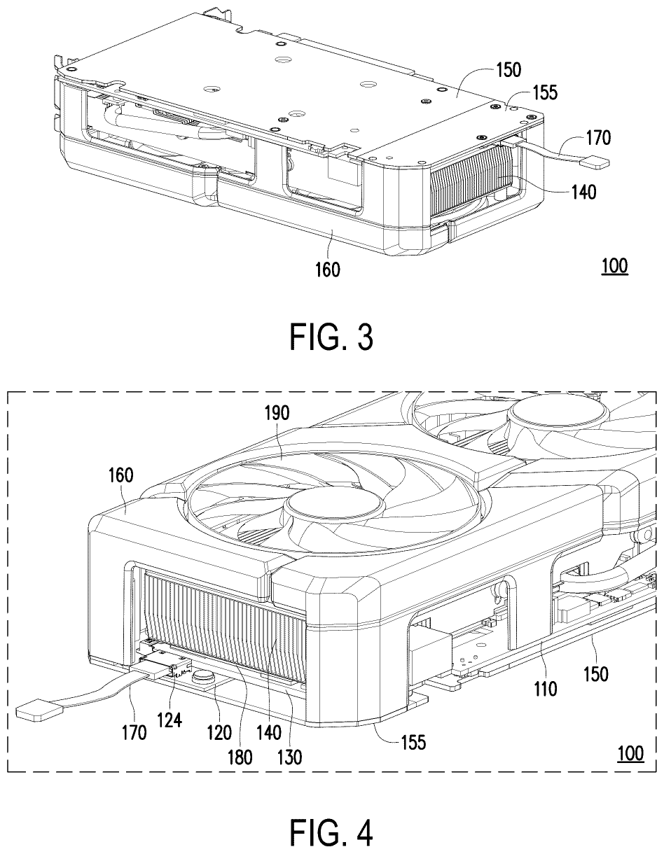

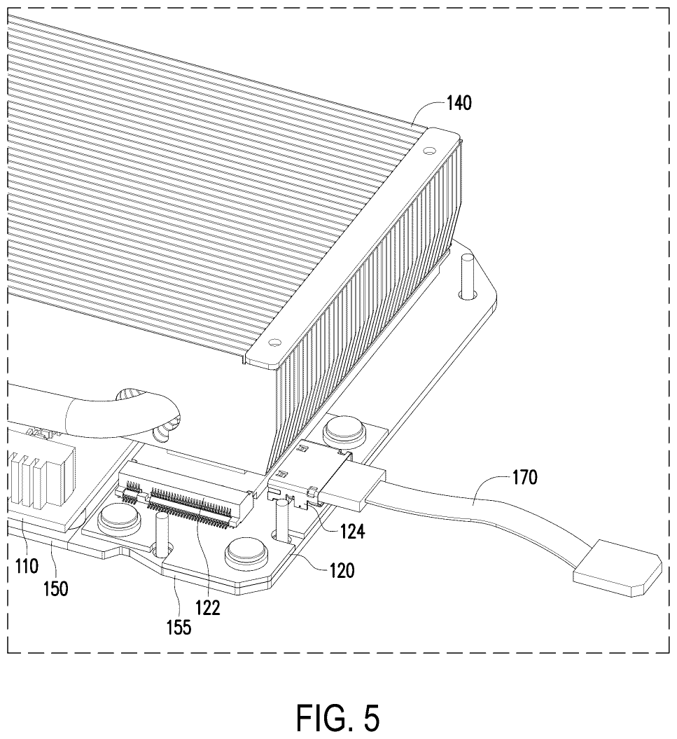

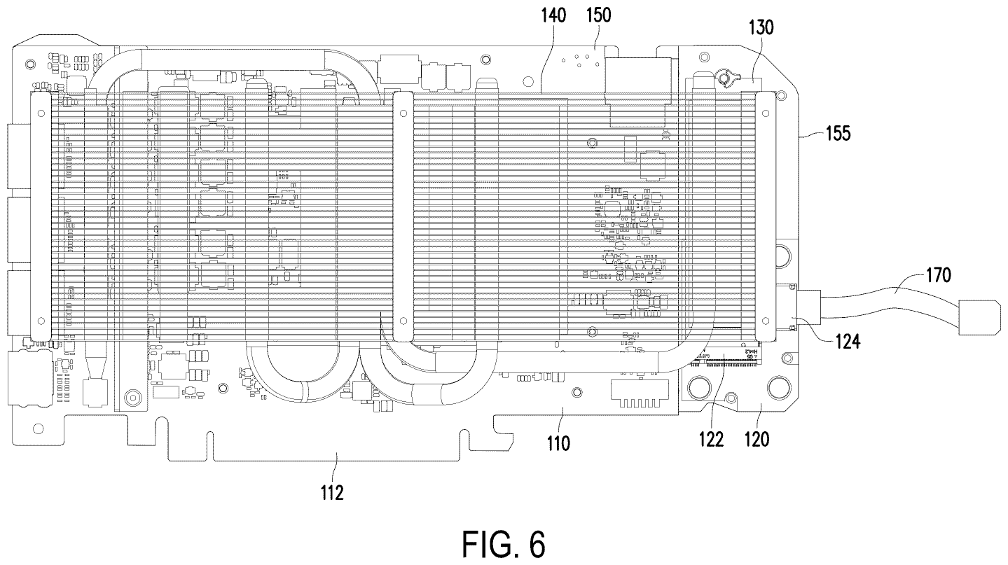

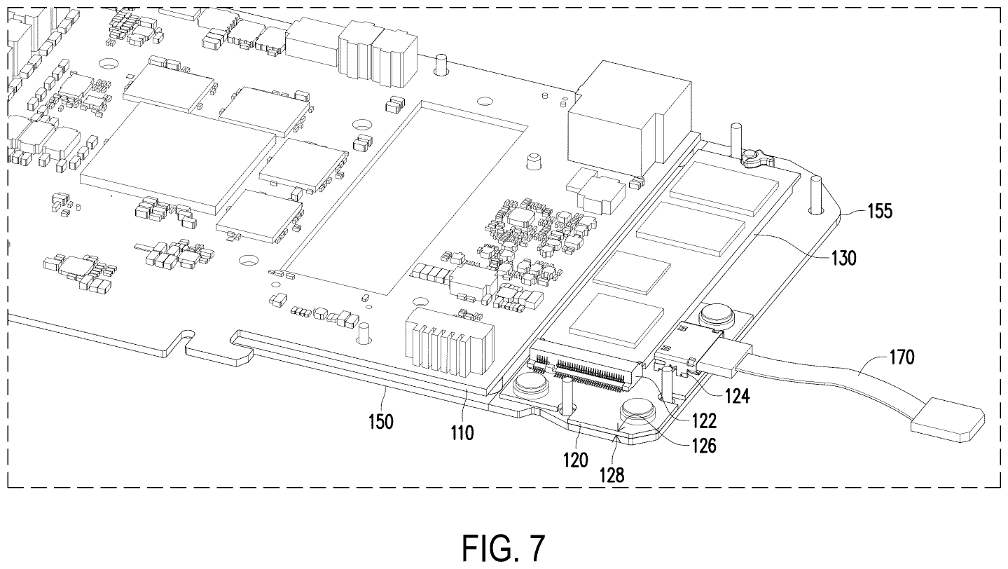

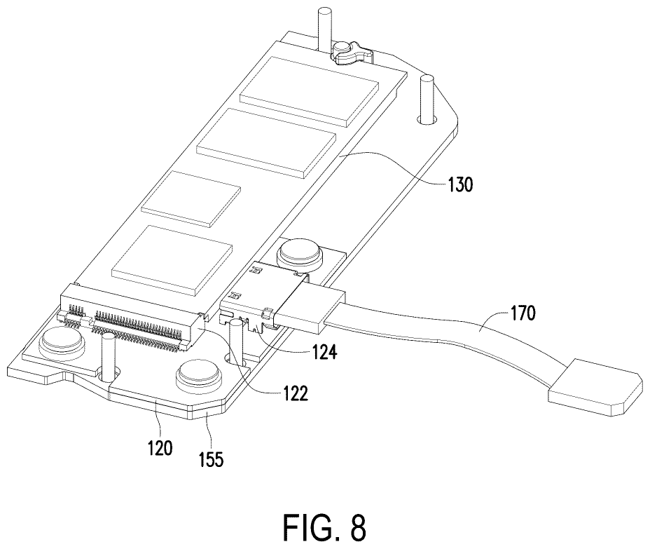

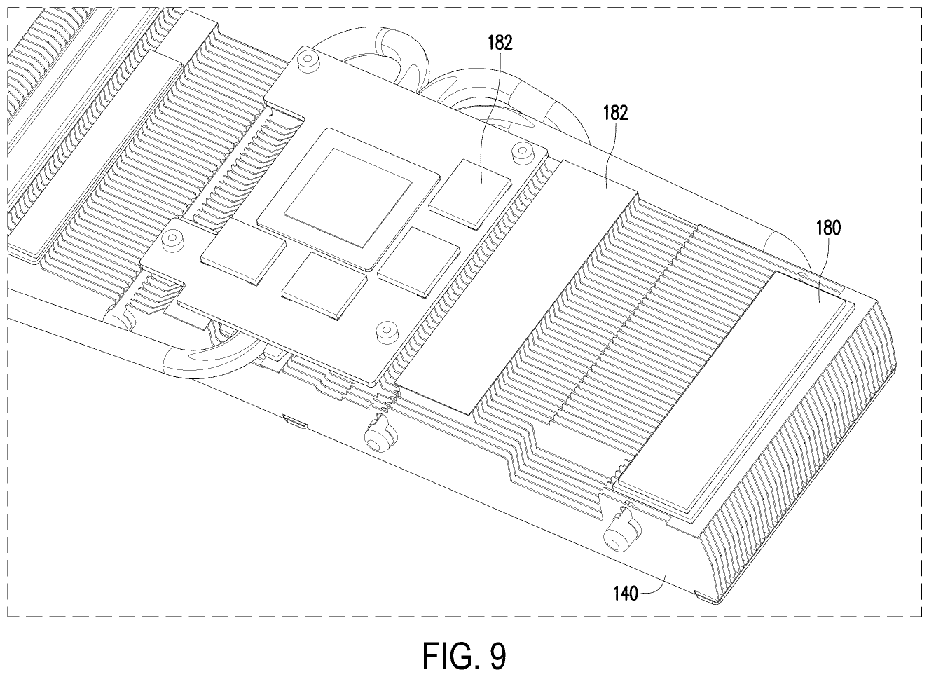

FIG. 1 to FIG. 3 are schematic diagrams of an expansion card module from different perspectives according to an embodiment of the disclosure. FIG. 4 is a partially enlarged schematic diagram of the expansion card module of FIG. 3 from another perspective. FIG. 5 is a schematic diagram concealing a cover plate of FIG. 4 from another perspective. FIG. 6 is a schematic diagram concealing a cover plate and a fan of FIG. 1. FIG. 7 is a schematic diagram concealing a heat sink of FIG. 5. FIG. 8 is a schematic diagram of a circuit board, a storage unit and a connection cable of FIG. 7. FIG. 9 is a schematic diagram of a bottom surface of a heat sink of FIG. 1.

Referring to FIG. 1 to FIG. 9, an expansion card module 100 of this embodiment includes an expansion card 110, a circuit board 120 (FIG. 4), a storage unit 130 (FIG. 4), and a heat sink 140 (FIG. 4). In this embodiment, the expansion card 110 is, for example, a display adapter, a port 112 of the expansion card 110 is, for example, a PCI-E interface, and the storage unit 130 is, for example, a solid-state drive (SSD). However, the types of the expansion card 110, the port 112, and the storage unit 130 are not limited thereto.

As can be seen from FIG. 7, in this embodiment, the circuit board 120 is disposed next to the expansion card 110 and includes a first connector 122 and a second connector 124. The first connector 122 and the second connector 124 are located on a first surface 126 of the circuit board 120 and face different directions. For example, the second connector 124 faces outwardly of the circuit board 120, such as in a direction away from the expansion card 110.

The storage unit 130 is pluggably disposed on the first connector 122 of the circuit board 120. The expansion card module 100 also includes a connection cable 170 that is pluggably disposed on the second connector 124. The storage unit 130 is connected to the circuit board 120 through the first connector 122, the circuit board 120 is connected to the connection cable 170 through the second connector 124, and the connection cable 170 is connectable to a slot (not shown) on a motherboard (not shown).

Thus, the storage unit 130 of the expansion card module 100 in this disclosure is electrically connected to the motherboard through the circuit board 120 and the connection cable 170 to transmit signals. Since the storage unit 130 does not need to transmit signals through the port 112 of the expansion card 110, there may be better compatibility between the storage unit 130 and the motherboard. In addition, since the storage unit 130 is not disposed on the expansion card 110, the storage unit 130 does not occupy the area of the expansion card 110 and does not affect the circuit layout of the expansion card 110.

The expansion card module 100 also includes a first backplane 150 and a second backplane 155. The expansion card 110 is fixed on the first backplane 150, and the circuit board 120 is fixed on the second backplane 155. The storage unit 130 may fix the end of the storage unit 130 to the first back panel 150 through a fixing structure such as a knob. In this embodiment, the first backplane 150 and the second backplane 155 are located on the same plane, but in other embodiments, the first backplane 150 and the second backplane 155 may also be located on different planes. The second backplane 155 is located on a second surface 128 of the circuit board 120 (FIG. 7).

As shown in FIG. 4, the expansion card module 100 further includes a cover plate 160 fixed to the first backplane 150 and the second backplane 155. The first backplane 150 and the second backplane 155 are fixed to the cover plate 160, for example, by locking, but are not limited thereto. In addition, the expansion card 110, the circuit board 120, the storage unit 130, the heat sink 140, and a fan 190 are located in a space surrounded by the cover plate 160, the first backplane 150, and the second backplane 155.

As can be seen from FIG. 8, in this embodiment, the storage unit 130 extends beyond the circuit board 120, so that a projection of the storage unit 130 onto the second backplane 155 extends beyond a range of a projection of the circuit board 120 onto the second backplane 155. That is, the size of the circuit board 120 does not need to be too large to save costs. In other embodiments, the projection of the storage unit 130 onto the second backplane 155 may also be within the range of the projection of the circuit board 120 onto the second backplane 155, and the size relationship between the storage unit 130 and the circuit board 120 is not limited thereto.

As shown in FIG. 5, the heat sink 140 is located next to the expansion card 110 and the storage unit 130 and is thermally coupled to the expansion card 110 and the storage unit 130. As shown in FIG. 6, a projection of the heat sink 140 onto the first backplane 150 partially overlaps with a projection of the expansion card 110 onto the first backplane 150, and a projection of the heat sink 140 onto the second backplane 155 at least partially overlaps with the projection of the storage unit 130 onto the second backplane 155. As shown in FIG. 9, the expansion card module 100 also includes heat conductive members 180 and 182 located between the heat sink 140 and the storage unit 130. Thus, the heat energy generated by the heat sink 140 and the storage unit 130 may be conducted to the heat sink 140 through the heat conductive members 180 and 182.

In addition, the storage unit 130 of the expansion card module 100 in this disclosure dissipates heat together with the expansion card module 100 through the heat sink 140, thus having a good heat dissipation effect. In other embodiments, if the quantity or area of the storage unit 130 is large, the size of the heat sink 140 may be correspondingly increased to provide a good heat dissipation effect for more storage units 130.

The storage unit of the expansion card module in this disclosure transmits signals through the circuit board. Since there is no need to transmit signals through the expansion card, the storage unit and the motherboard may have better compatibility. In addition, the storage unit of the expansion card module in this disclosure dissipates heat through the heat sink together with the expansion card, thus having a good heat dissipation effect.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An expansion card module, comprising:
an expansion card;
a circuit board, disposed next to the expansion card, comprising a first connector and a second connector;
a storage unit, pluggably disposed on the first connector of the circuit board; and
a heat sink, located next to the expansion card and the storage unit, thermally coupled to the expansion card and the storage unit.

2. The expansion card module according to claim 1, further comprising a first backplane and a second backplane, the expansion card fixed on the first backplane, and the circuit board fixed on the second backplane.

3. The expansion card module according to claim 2, further comprising a cover plate fixed to the first backplane and the second backplane, the expansion card, the circuit board, the storage unit, and the heat sink located in a space surrounded by the cover plate, the first backplane, and the second backplane.

4. The expansion card module according to claim 2, wherein the first backplane and the second backplane are located on the same plane.

5. The expansion card module according to claim 2, wherein the first connector and the second connector are located on a first surface of the circuit board and face different directions, and the second backplane is located on a second surface of the circuit board.

6. The expansion card module according to claim 2, wherein a projection of the storage unit onto the second backplane extends beyond a range of a projection of the circuit board onto the second backplane.

7. The expansion card module according to claim 2, wherein a projection of the heat sink onto the second backplane at least partially overlaps a projection of the storage unit onto the second backplane.

8. The expansion card module according to claim 2, wherein a projection of the heat sink onto the first backplane partially overlaps a projection of the expansion card onto the first backplane.

9. The expansion card module according to claim 1, further comprising a connection cable pluggably disposed on the second connector.

10. The expansion card module according to claim 1, further comprising a heat conductive member located between the heat sink and the storage unit.
